(19) United States
(12) Patent Application Publication
(10) Pub. No.: US 2025/0022896 A1
(43) Pub. Date: Jan. 16, 2025

(54) IMAGE SENSOR

(71) Applicant: Samsung Electronics Co., LTD, Suwon-si (KR)

(72) Inventors: Junsung Park, Suwon-si (KR); Jonghoon Park, Suwon-si (KR); Yun Ki Lee, Suwon-si (KR)

(73) Assignee: Samsung Electronics Co., LTD, Suwon-si (KR)

(21) Appl. No.: 18/430,333

(22) Filed: Feb. 1, 2024

(30) Foreign Application Priority Data
Jul. 10, 2023 (KR) 10-2023-0089000

(51) Int. Cl. H01L 27/146

(52) U.S. Cl. CPC H01L 27/14621; H01L 27/14627; H01L 27/1463; H01L 27/14636

(57) ABSTRACT

An image sensor includes: a semiconductor substrate including a pixel array region, the pixel array region including a center pixel region and an edge pixel region enclosing the center pixel region in a plan view; color filter groups on the pixel array region, each color filter group of the color filter groups including color filters arranged in a same number of rows and columns; and micro lenses covering the color filter groups, respectively, wherein the color filter groups include center color filter groups on the center pixel region and edge color filter groups on the edge pixel region, and at least two color filters of the color filters in each of the edge color filter groups have thicknesses that are different from each other.

### CROSS-REFERENCE TO RELATED APPLICATIONS

This application claims priority under 35 U.S.C. § 119 to Korean Patent Application No. 10-2023-0089000, filed on Jul. 10, 2023, in the Korean Intellectual Property Office, the entire contents of which are incorporated by reference herein.

### BACKGROUND

The present disclosure relates to an image sensor, and in particular, to an image sensor with improved electrical and optical properties.

An image sensor is a device that converts optical signals into electrical signals. With the development of the computer and communications industries, there is an increasing demand for high-performance image sensors in a variety of applications such as digital cameras, camcorders, personal communication systems, gaming machines, security cameras, micro-cameras for medical applications, and/or robots. The image sensors are generally classified into charge-coupled device (CCD) and complementary metal-oxide semiconductor (CMOS) image sensors. The CMOS image sensor can be operated in a simplified manner, and since signal-processing circuits of the CMOS image sensor can be integrated on a single chip, it is possible to reduce a size of a product therewith. In addition, since the CMOS image sensor can be operated with a relatively low power consumption, it can be easily applied to an electronic device with a limited battery capacity. Furthermore, since the CMOS image sensor can be fabricated using the existing CMOS fabrication techniques, it is possible to reduce a manufacturing cost thereof. In addition, owing to an increase in resolution of CMOS image sensors, the use of CMOS image sensors is rapidly increasing.

### SUMMARY

One or more embodiments provide an image sensor with improved optical properties.

According to an aspect of an example embodiment, an image sensor includes: a semiconductor substrate including a pixel array region, the pixel array region including a center pixel region and an edge pixel region enclosing the center pixel region in a plan view; color filter groups on the pixel array region, each color filter group of the color filter groups including color filters arranged in a same number of rows and columns; and micro lenses covering the color filter groups, respectively, wherein the color filter groups include center color filter groups on the center pixel region and edge color filter groups on the edge pixel region, and at least two color filters of the color filters in each of the edge color filter groups have thicknesses that are different from each other.

According to an aspect of an example embodiment, an image sensor includes: a semiconductor substrate of a first conductivity type, the semiconductor substrate including a pixel array region, a first surface and a second surface opposite to the first surface; a photoelectric conversion region in the pixel array region, the photoelectric conversion region including impurities of a second conductivity type; color filter groups covering at least a portion of the pixel array region, each color filter group of the color filter groups including a first color filter, a second color filter, a third color filter, and a fourth color filter arranged in two rows and two columns; and micro lenses covering the color filter groups, respectively, wherein the pixel array region includes a center pixel region and an edge pixel region enclosing the center pixel region in a plan view, the color filter groups include center color filter groups on the center pixel region and edge color filter groups on the edge pixel region, and in each edge color filter group of the edge color filter groups, a thickness of the first color filter is larger than a thickness of the second color filter.

According to an aspect of an example embodiment, an image sensor includes: a semiconductor substrate including a light-receiving region, a light-blocking region, a pad region, a first surface, and a second surface which is opposite to the first surface; a pixel isolation structure in the light-receiving region and the light-blocking region of the semiconductor substrate, the pixel isolation structure defining pixel regions; photoelectric conversion regions in the light-receiving region and the light-blocking region of the semiconductor substrate; color filter groups on the first surface, each color filter group of the color filter groups including a first color filter, a second color filter, a third color filter, and a fourth color filter arranged in two rows and two columns; a transfer gate electrode on the second surface; a pixel circuit layer on the second surface; and micro lenses covering the color filter groups, respectively, wherein the light-receiving region includes a center pixel region and an edge pixel region enclosing the center pixel region in a plan view, the color filter groups include center color filter groups on the center pixel region and edge color filter groups on the edge pixel region, and in each of the edge color filter groups, a thickness of the first color filter is larger than a thickness of the second color filter.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 is a block diagram illustrating an image sensor according to an embodiment;

FIG. 2A is a circuit diagram that illustrates a unit pixel of an image sensor according to an embodiment;

FIG. 2B is a circuit diagram that illustrates a unit pixel of an image sensor according to an embodiment;

FIG. 3 is a plan view illustrating an image sensor according to an embodiment;

FIG. 4 is an enlarged plan view illustrating a light-receiving region of FIG. 3;

FIG. 5A is an enlarged plan view illustrating a portion P1 of FIG. 4;

FIG. 5B is an enlarged plan view illustrating a portion P1′ of FIG. 4;

FIG. 6A is a sectional view, which is taken along line A-A′ of FIG. 5A to illustrate an image sensor according to an embodiment;

FIG. 6B is a sectional view, which is taken along line B-B′ of FIG. 5A to illustrate an image sensor according to an embodiment;

FIG. 6C is a sectional view, which is taken along line C-C′ of FIG. 5A to illustrate an image sensor according to an embodiment;

FIG. 7 is an enlarged plan view illustrating a portion P2 of FIG. 4;

FIG. 8A is a sectional view, which is taken along line I-I′ of FIG. 7 to illustrate an image sensor according to an embodiment;

FIG. 8B is a sectional view, which is taken along line II-II′ of FIG. 7 to illustrate an image sensor according to an embodiment;

FIG. 8C is a sectional view, which is taken along line III-III′ of FIG. 7 to illustrate an image sensor according to an embodiment;

FIG. 9 is a plan view illustrating image sensors according to an embodiment;

FIG. 10 is a plan view illustrating image sensors according to an embodiment;

FIG. 11 is a sectional view illustrating image sensors according to an embodiment;

FIG. 12 is a sectional view illustrating image sensors according to an embodiment;

FIG. 13 is a sectional view illustrating image sensors according to an embodiment;

FIG. 14 is a plan view illustrating an image sensor according to an embodiment;

FIG. 15 is a sectional view, which is taken along a line A-A′ of FIG. 14 to illustrate an image sensor according to an embodiment;

FIG. 16 is a plan view illustrating an image sensor according to an embodiment;

FIG. 17 is a sectional view, which is taken along a line A-A′ of FIG. 16 to illustrate an image sensor according to an embodiment;

FIG. 18A is a sectional view, taken along the line A-A′ of FIG. 4 to illustrate an image sensor according to an embodiment; and

FIG. 18B is a sectional view, taken along the line A-A′ of FIG. 4 to illustrate an image sensor according to an embodiment.

### DETAILED DESCRIPTION

Example embodiments will now be described more fully with reference to the accompanying drawings. Like reference numerals in the drawings denote like elements, and thus their description will be omitted.

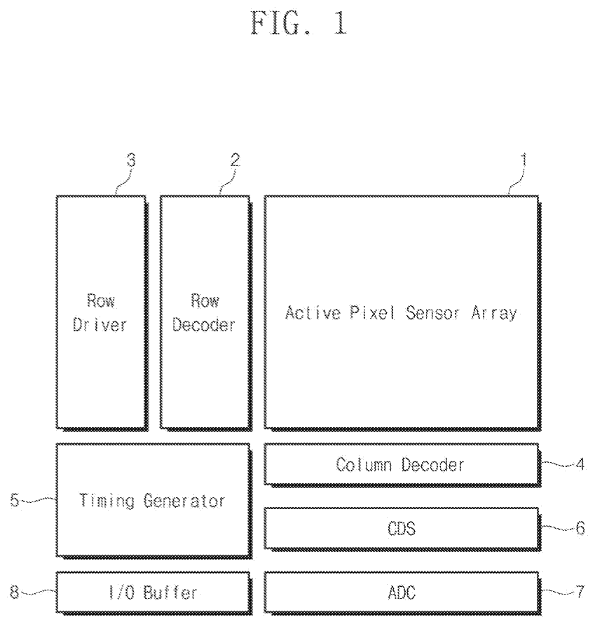

FIG. 1 is a block diagram illustrating an image sensor according to an embodiment.

Referring to FIG. 1, the image sensor may include an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

The active pixel sensor array 1 may include a plurality of unit pixels that are two-dimensionally arranged and are configured to convert optical signals to electrical signals. The active pixel sensor array 1 may be driven by a plurality of driving signals, such as a pixel selection signal, a reset signal, and a charge transfer signal, which are transmitted from the row driver 3. In addition, the converted electrical signals may be provided to the correlated double sampler 6.

The row driver 3 may be configured to provide the driving signals for driving the plurality of unit pixels to the active pixel sensor array 1, based on the result decoded by the row decoder 2. In the case where the unit pixels are arranged in a matrix shape (i.e., in rows and columns), the driving signals may be provided to respective rows.

The timing generator 5 may be configured to provide timing and control signals to the row decoder 2 and the column decoder 4.

The CDS 6 may be configured to receive the electric signals generated in the active pixel sensor array 1 and to perform a holding and sampling operation on the received electric signals. For example, the CDS 6 may perform a double sampling operation on a specific noise level and a signal level of the electric signal and may output a difference level corresponding to a difference between the noise and signal levels.

The ADC 7 may be configured to convert analog signals, which correspond to the difference level output from the CDS 6, into digital signals, and then to output the converted digital signals to the I/O buffer 8.

The I/O buffer 8 may be configured to latch the digital signal and to sequentially output the latched digital signals to an image signal processing unit, based on the result decoded by the column decoder 4.

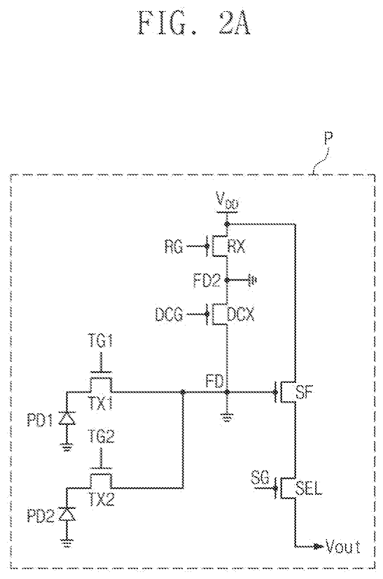

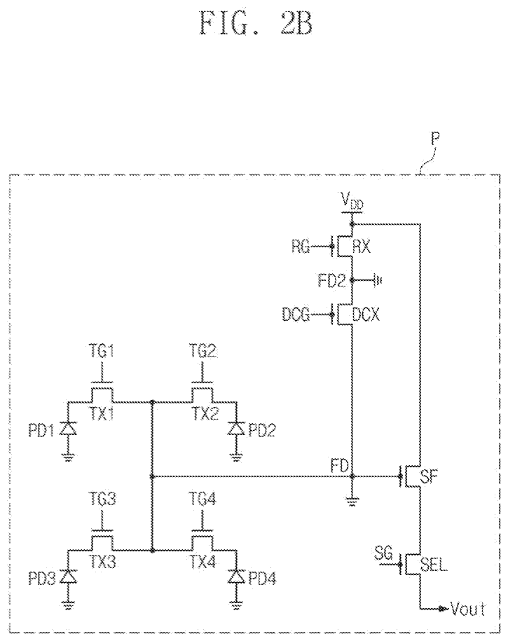

FIGS. 2A and 2B are circuit diagrams, each of which illustrates a unit pixel of an image sensor according to an embodiment.

Referring to FIG. 2A, a unit pixel P may include first and second photoelectric conversion devices PD1 and PD2, first and second transfer transistors TX1 and TX2, and four pixel transistors. For example, each of the four pixel transistors may correspond to a reset transistor RX, a source follower transistor SF, a selection transistor SEL, and a double conversion gain transistor DCX, but embodiments of the disclosure are not limited to this example. In other words, the pixel transistors may be variously provided in each unit pixel P.

The first and second photoelectric conversion devices PD1 and PD2 may be configured to generate electric charges in response to an incident light, and in this case, the generated electric charges may be accumulated in the first and second photoelectric conversion devices PD1 and PD2. In an embodiment, the first and second photoelectric conversion devices PD1 and PD2 may be photodiodes, photo-transistors, photo-gates, pinned photodiodes (PPDs), and combinations thereof.

The first and second transfer transistors TX1 and TX2 may be configured to transfer the electric charges, which are accumulated in the first and second photoelectric conversion devices PD1 and PD2, to a floating diffusion region FD. The first and second transfer transistors TX1 and TX2 may be controlled by signals applied to first and second transfer gate electrodes TG1 and TG2. The first and second transfer transistors TX1 and TX2 may share the floating diffusion region FD, but embodiments of the disclosure are not limited to this example. For example, the first and second transfer transistors TX1 and TX2 may be respectively connected to different floating diffusion regions FD from each other.

The floating diffusion region FD may be configured to receive the electric charges, which are generated in the first or second photoelectric conversion device PD1 or PD2, and to cumulatively store the electric charges therein. The source follower transistor SF may be controlled by an amount of photocharges that are accumulated in the floating diffusion region FD.

The reset transistor RX may periodically initialize the electric charges, which are accumulated in the floating diffusion region FD, by a reset signal applied to a reset gate electrode RG. In detail, the reset transistor RX may include a drain terminal, which is connected to the double conversion gain transistor DCX, and a source terminal, which is connected to a pixel power voltage VDD. If the reset transistor RX and the double conversion gain transistor DCX are turned on, the pixel power voltage VDD may be transferred to the floating diffusion region FD. Thus, the electric charges may be discharged from the floating diffusion region FD, and in this case, the floating diffusion region FD may be initialized.

The double conversion gain transistor DCX may be provided between and connected to the floating diffusion region FD and the reset transistor RX. The double conversion gain transistor DCX may control a conversion gain by changing the capacitance of the floating diffusion region FD in response to a double conversion gain control signal. Different conversion gains may be realized through the operation of the double conversion gain transistor DCX. Thus, the double conversion gain transistor DCX may be turned on in a high-brightness mode and may be turned off in a low-brightness mode.

The source follower transistor SF may be a source follower buffer amplifier, which is configured to generate a source-drain current in proportion to a charge amount of a first floating diffusion region FDI to be input to a source follower gate electrode. The source follower transistor SF may amplify a variation in electric potential of the floating diffusion region FD and may output the amplified signal to an output line Vout through the selection transistor SEL. The source follower transistor SF may include a source terminal, which is connected to the pixel power voltage VDD, and a drain terminal, which is connected to a source terminal of the selection transistor SEL.

The selection transistor SEL may be used to select a row of the unit pixels P to be read out during a read operation. If the selection transistor SEL is turned on by a selection signal applied to a selection gate electrode SG, an electrical signal, which is output to a drain electrode of the source follower transistor SF, may be output to the output line Vout.

Referring to FIG. 2B, the unit pixel P may include first to fourth photoelectric conversion devices PD1, PD2, PD3, and PD4, first to fourth transfer transistors TX1, TX2, TX3, and TX4, and four pixel transistors.

The first to fourth transfer transistors TX1, TX2, TX3, and TX4 may share the floating diffusion region FD. The first to fourth transfer transistors TX1, TX2, TX3, and TX4 may be controlled by signals applied to first to fourth transfer gate electrodes TG1, TG2, TG3, and TG4.

The four pixel transistors may correspond to the reset transistor RX, the source follower transistor SF, the selection transistor SEL, and the double conversion gain transistor DCX described with reference to FIG. 2A.

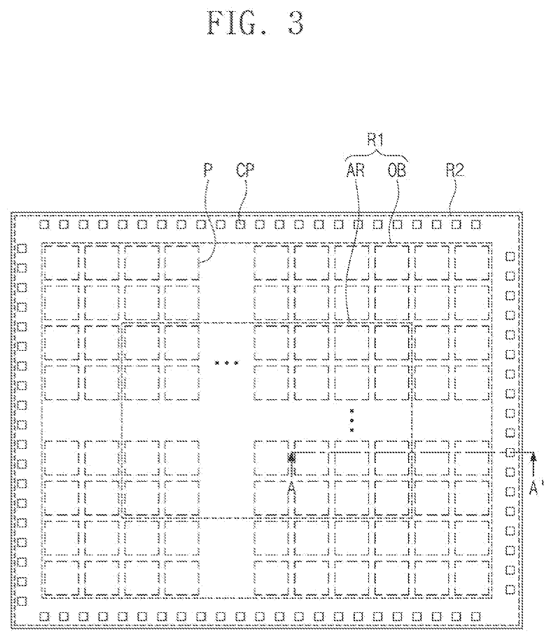

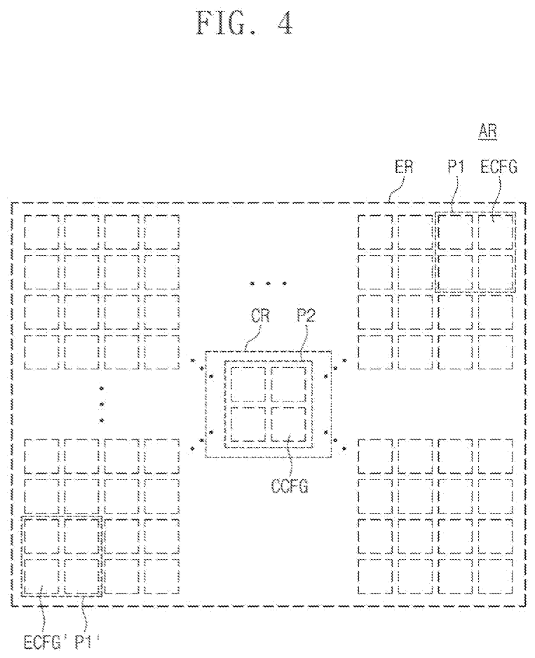

FIG. 3 is a plan view illustrating an image sensor according to an embodiment. FIG. 4 is an enlarged plan view illustrating a light-receiving region of FIG. 3.

Referring to FIGS. 3 and 4, an image sensor may include a pixel array region R1 and a pad region R2.

The pixel array region R1 may include a plurality of pixels P, which are two-dimensionally arranged in two different directions (e.g., in a first direction D1 and a second direction D2). Each of the pixels P may include a photoelectric conversion device and readout devices. Each of the pixels P of the pixel array region R1 may be configured to output an electrical signal, which is produced by incident light.

The pixel array region R1 may include a light-receiving region AR and a light-blocking region OB. When viewed in a plan view, the light-blocking region OB may enclose the light-receiving region AR. For example, when viewed in a plan view, the light-blocking region OB may be provided to enclose the light-receiving region AR in four different directions (e.g., up, down, left, and rights directions). In an embodiment, reference pixels P, to which light is not incident, may be provided in the light-blocking region OB, and in this case, by comparing a charge amount, which is obtained from the unit pixel P in the light-receiving region AR, with an amount of charges generated in the reference pixels P, it may be possible to calculate a magnitude of an electrical signal generated by the unit pixel P.

In the light-receiving region AR, the pixel array region R1 may include a center pixel region CR, in which a plurality of pixels are disposed, and an edge pixel region ER, which is provided to enclose the center pixel region CR when viewed in a plan view. That is, the edge pixel region ER may be provided to enclose the center pixel region CR in four different directions (e.g., up, down, left, and rights directions), when viewed in a plan view. Here, an angle of an incident light, which is incident into the edge pixel region ER, may be different from an angle of an incident light, which is incident into the center pixel region CR. Color filters and micro lenses may be disposed on the pixel array region R1.

The color filters may be disposed on the pixel array region R1 to cover the reference pixels P, respectively. The color filters may be arranged in n rows and n columns (i.e. a same number of rows and columns) to form color filter groups ECFG, ECFG′, and CCFG.

The color filters may include red, green, and blue color filters. The red, green, and blue color filters may be configured to allow for selective transmission of an incident light that is incident from the outside.

The micro lenses may be configured to condense the incident light that is incident from the outside. The micro lenses may be two-dimensionally arranged in two different direction (e.g., the first and second directions D1 and D2), when viewed in a plan view.

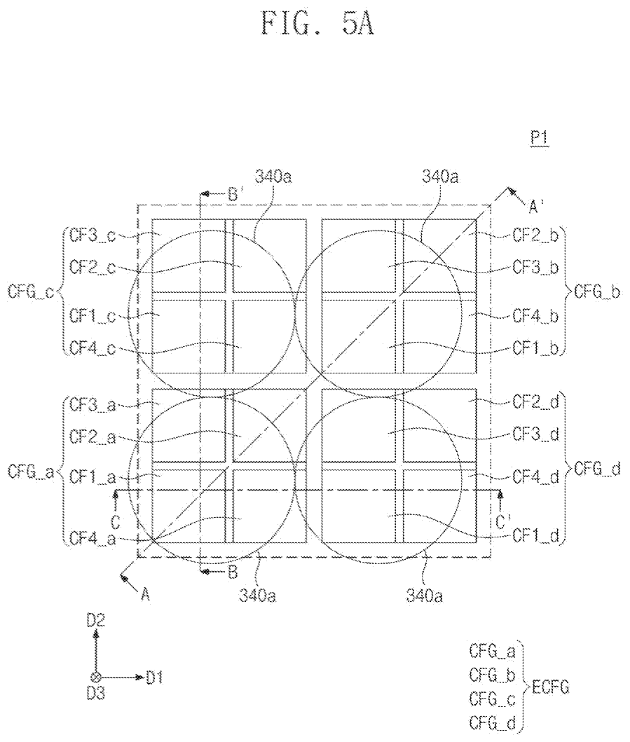

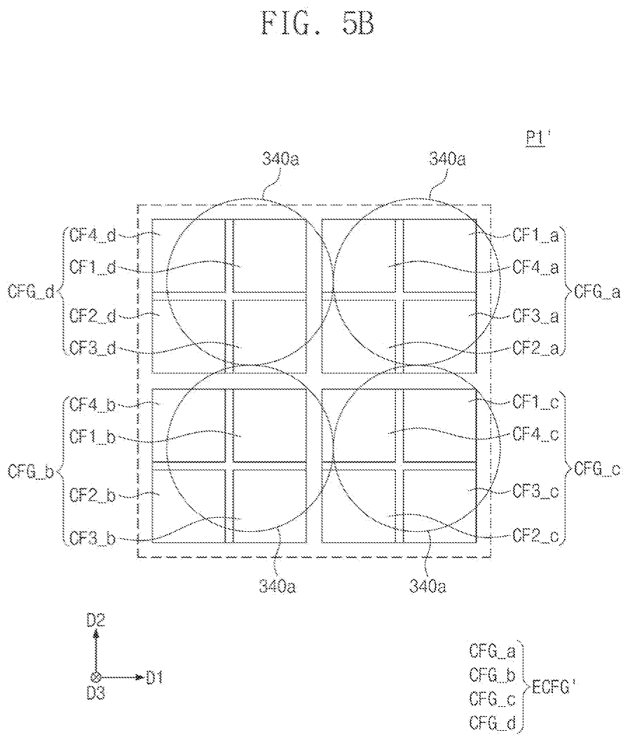

In an embodiment, each of the micro lenses may be provided to cover one of the color filter groups. In an embodiment, each of the micro lens may cover a color filter group, in which the color filters are arranged in two rows and two columns. The color filters and the micro lenses will be described in more detail with reference to FIGS. 5A to 10.

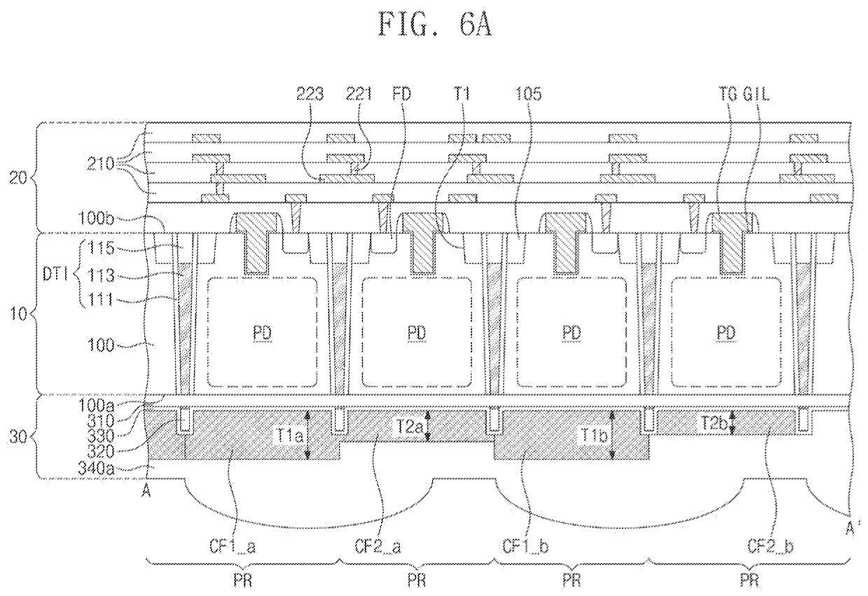

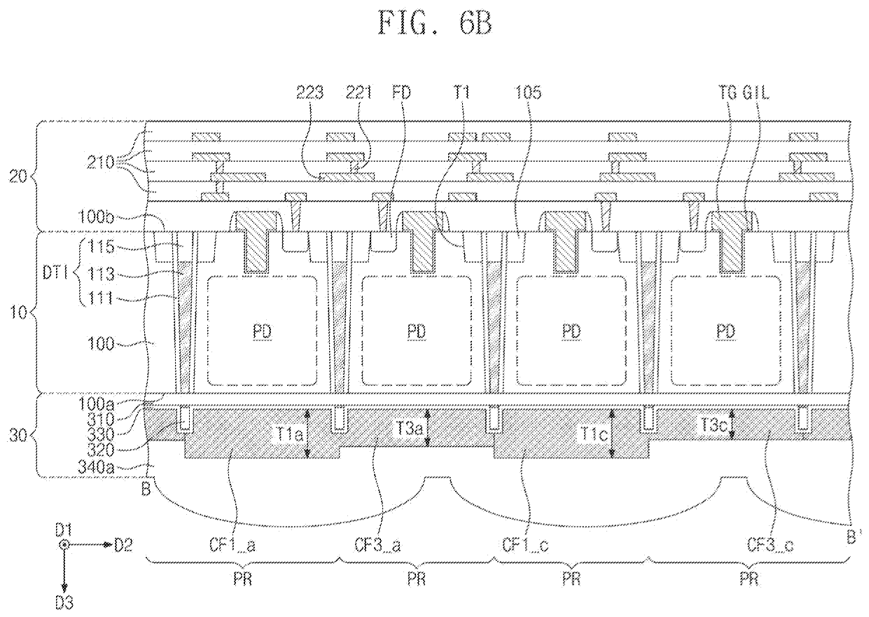

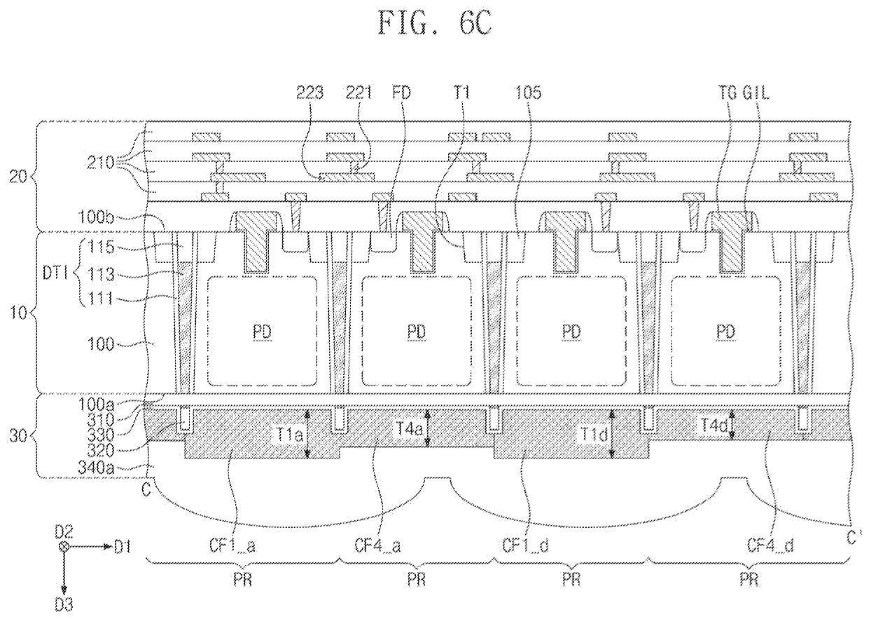

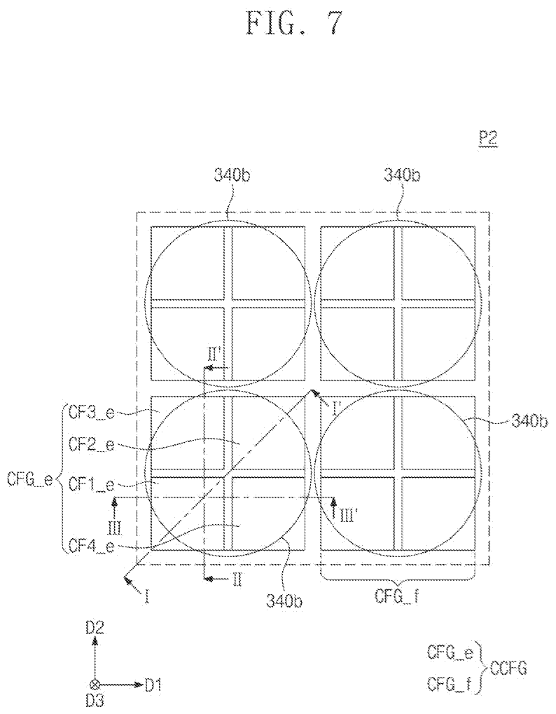

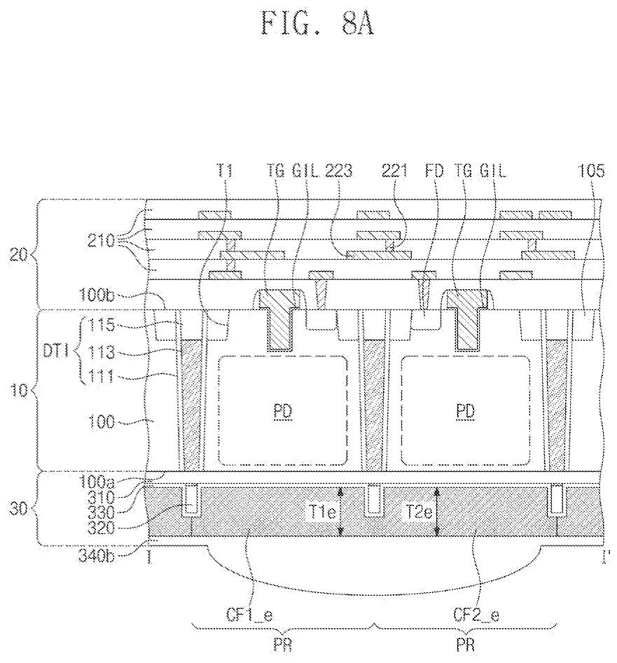

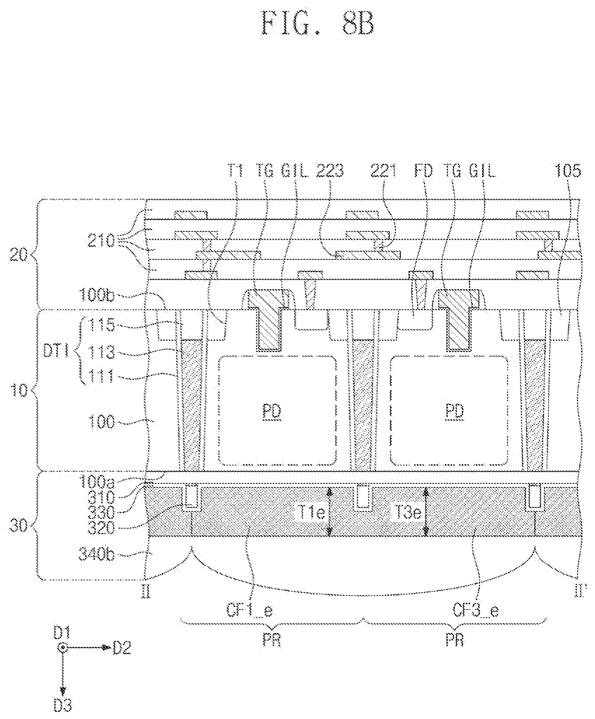

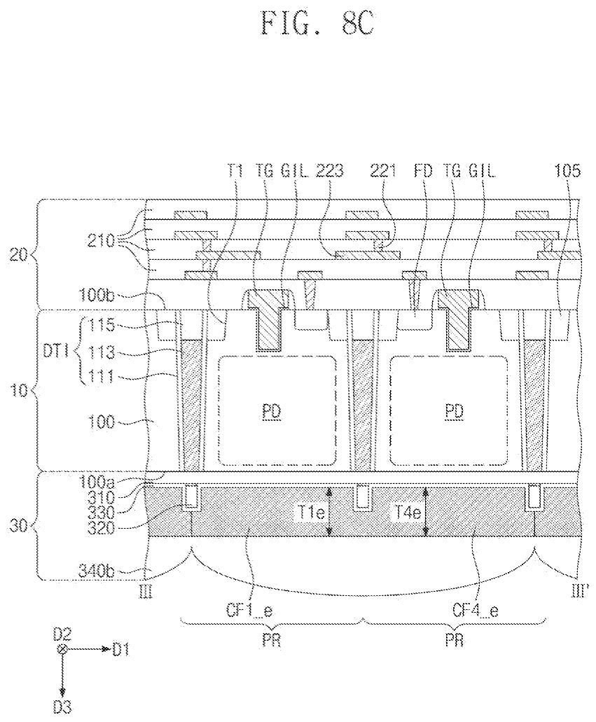

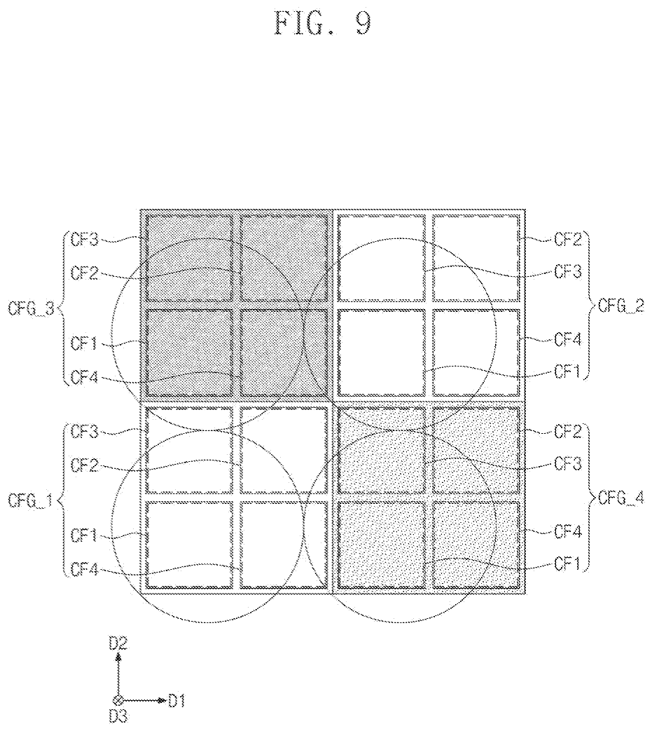

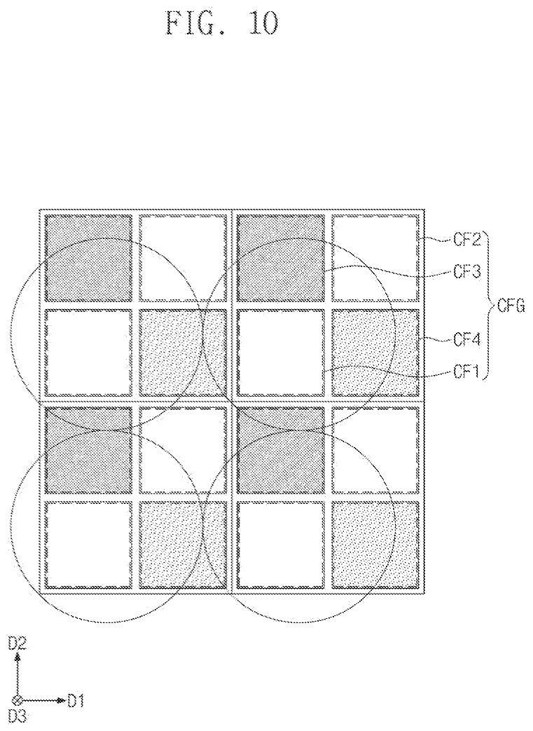

FIG. 5A is an enlarged plan view illustrating a portion P1 of FIG. 4. FIG. 5B is an enlarged plan view illustrating a portion P1′ of FIG. 4. FIGS. 6A to 6C are sectional views, which are taken along lines A-A′, B-B′, and C-C′ of FIG. 5A to illustrate an image sensor according to an embodiment. FIG. 7 is an enlarged plan view illustrating a portion P2 of FIG. 4. FIGS. 8A to 8C are sectional views, which are taken along lines I-I′, II-II′, and III-III′ of FIG. 7 to illustrate an image sensor according to an embodiment. FIGS. 9 and 10 are plan views illustrating image sensors according to some embodiments.

Referring to FIGS. 5A to 10, the image sensor may include a photoelectric conversion layer 10, a pixel circuit layer 20, and an optically-transparent layer 30, when viewed in a vertical section.

The photoelectric conversion layer 10 may be disposed between the pixel circuit layer 20 and the optically-transparent layer 30, when viewed in a vertical section. The photoelectric conversion layer 10 may be configured to convert light, which is incident from the outside, to electrical signals. The photoelectric conversion layer 10 may include a semiconductor substrate 100 and a pixel isolation structure DTI, a barrier region 103, and photoelectric conversion regions PD, which are placed in the semiconductor substrate 100.

In detail, the semiconductor substrate 100 may have a first surface 100a and a second surface 100b, which are opposite to each other. The semiconductor substrate 100 may be a substrate including a bulk silicon substrate and an epitaxial layer, which are sequentially stacked and are of a first conductivity type (e.g., p-type), and in the case where the bulk silicon substrate is removed during a fabrication process of an image sensor, the semiconductor substrate 100 may be composed of only the p-type epitaxial layer. In an embodiment, the semiconductor substrate 100 may be a bulk semiconductor substrate, in which a well of the first conductivity type is formed. The first surface 100a of the semiconductor substrate 100 may face the color filters, and the second surface 100b of the semiconductor substrate 100 may face the pixel circuit layer 20.

In each of pixel regions PR, a device isolation layer 105 may be disposed near the second surface 100b of the semiconductor substrate 100. The device isolation layer 105 may be provided in a device isolation trench T1, which is formed by recessing the second surface 100b of the semiconductor substrate 100. The device isolation layer 105 may be formed of or include an insulating material. The device isolation layer 105 may be formed near the second surface 100b to define an active portion in the semiconductor substrate 100. For example, the device isolation layer 105 may define first and second active portions in the semiconductor substrate 100. The first and second active portions may be spaced apart from each other in each of the pixel regions PR and may have different sizes from each other.

The pixel isolation structure DTI may be provided in a pixel isolation trench, which is formed by recessing the first surface 100a of the semiconductor substrate 100. The pixel isolation structure DTI may define a plurality of pixel regions PR. The pixel isolation structure DTI may penetrate the semiconductor substrate 100 from the second surface 100b to the first surface 100a. The pixel isolation structure DTI may be provided to penetrate a portion of the device isolation layer 105.

The pixel isolation structure DTI may include portions, which are extended in the first direction D1 and parallel to each other, and portions, which are extended in the second direction D2 and parallel to each other. The pixel isolation structure DTI may be provided to enclose each of the pixel regions PR or each of the photoelectric conversion regions PD, when viewed in a plan view.

The pixel isolation structure DTI may have an upper width at a level near the second surface 100b of the semiconductor substrate 100 and may have a lower width at a level near the first surface 100a of the semiconductor substrate 100. The lower width may be smaller than the upper width. For example, the width of the pixel isolation structure DTI may decrease as it moves from the second surface 100b of the semiconductor substrate 100 to the first surface 100a. The pixel isolation structure DTI may have a length in a third direction D3. A length of the pixel isolation structure DTI may be substantially equal to a vertical thickness of the semiconductor substrate 100.

The photoelectric conversion regions PD may be provided in the semiconductor substrate 100 of each of the pixel regions PR. The photoelectric conversion regions PD may generate photocharges in proportion to an intensity of an incident light. The photoelectric conversion regions PD may be formed by injecting impurities, which are of a second conductivity type different from the semiconductor substrate 100, into the semiconductor substrate 100. The photoelectric conversion region PD of the second conductivity type and the semiconductor substrate 100 of the first conductivity type may form a pn junction serving as a photodiode. In an embodiment, each of the photoelectric conversion regions PD may be provided to have a difference in impurity concentration between portions adjacent to the first and second surfaces 100a and 100b, thereby having a non-vanishing gradient in potential between the first and second surfaces 100a and 100b of the semiconductor substrate 100. For example, the photoelectric conversion regions PD may include a plurality of impurity regions which are vertically stacked.

The pixel circuit layer 20 may be disposed on the second surface 100b of the semiconductor substrate 100. The pixel circuit layer 20 may include pixel circuits (e.g., MOS transistors), which are electrically connected to the photoelectric conversion regions PD. For example, the pixel circuit layer 20 may include the pixel transistors (e.g., the reset transistor RX, the selection transistor SEL, the double conversion gain transistor DCX, and the source follower transistor SF) described with reference to FIG. 2A.

A transfer gate electrode TG may be located on the second surface 100b of the semiconductor substrate 100. The transfer gate electrode TG may be provided to penetrate a portion of the semiconductor substrate 100. For example, when viewed in a vertical section, the transfer gate electrode TG may have a shape of the letter ‘T’. A gate insulating layer GIL may be interposed between the transfer gate electrode TG and the semiconductor substrate 100.

The floating diffusion region FD may be provided in a portion of a first active portion located at a side of the transfer gate electrode TG. The floating diffusion region FD may be formed by injecting impurities into the semiconductor substrate 100 and may have a conductivity type different from that of the semiconductor substrate 100. For example, the floating diffusion region FD may be an impurity region (e.g., of the second conductivity type).

At least one pixel transistor may be provided in the second active portion in each of the pixel regions PR. The pixel transistor, which is provided in each pixel region PR, may be at least one of the reset transistor RX, the source follower transistor SF, the double conversion gain transistor DCX, and the selection transistor SEL described with reference to FIGS. 2A and 2B. The pixel transistor may include a pixel gate electrode, which is provided to cross the second active portion, and source/drain regions, which are provided in the second active portion and at both sides of the pixel gate electrode. The pixel gate electrode may have a bottom surface that is parallel to a top surface of the second active portion. The pixel gate electrode may be formed of or include at least one of doped polysilicon, metallic materials, conductive metal nitride materials, conductive metal silicide materials, conductive metal oxide materials, or combinations thereof.

Interlayer insulating layers 210 may be placed on the second surface 100b of the semiconductor substrate 100 and may be composed of a plurality of layers. The interlayer insulating layers 210 may cover an interconnection structure, which is connected to the transfer gate electrode TG and the pixel circuits. The interconnection structure may include metal lines 223 and contact plugs 221, which connects the metal lines 223 to each other.

The optically-transparent layer 30 may be disposed on the first surface 100a of the semiconductor substrate 100. The optically-transparent layer 30 may include a planarization insulating layer 310, a light-blocking pattern 320, a protection layer 330, color filters CF, micro lenses 340a and 340b, and a passivation layer. The optically-transparent layer 30 may be configured to perform an operation of focusing and filtering light, which is incident from the outside, and to provide the light to the photoelectric conversion layer 10.

In detail, the planarization insulating layer 310 may cover the first surface 100a of the semiconductor substrate 100. The planarization insulating layer 310 may be formed of a transparent insulating material and may include a plurality of layers. The planarization insulating layer 310 may be formed of an insulating material whose refractive index is different from the semiconductor substrate 100. The planarization insulating layer 310 may be formed of or include at least one of metal oxide and/or silicon oxide. For example, the planarization insulating layer 310 may be formed of or include at least one of Al₂O₃, CeF₃, HfO₂, ITO, MgO, Ta₂O₅, TiO₂, ZrO₂, Si, Ge, ZnSe, ZnS, or PbF₂. Alternatively, the planarization insulating layer 310 may be formed of or include at least one of organic materials (e.g., siloxane resin, benzocyclobutene (BCB), polyimide, acryl, parylene C, poly(methyl methacrylate) (PMMA), polyethylene terephthalate (PET), or the like), which have high refractive indices. In addition, the planarization insulating layer 310 may be formed of or include at least one of strontium titanate (SrTiO₃), polycarbonate, glass, bromine, sapphire, cubic zirconia, potassium Niobate (KNbO₃), moissanite (SiC), gallium (III) phosphide (GaP), or gallium (III) arsenide (GaAs).

The light-blocking pattern 320 may be disposed on the planarization insulating layer 310 to separate the color filter groups CFG from each other. When viewed in a plan view, the light-blocking pattern 320 may have a lattice shape, similar to the pixel isolation structure DTI. The light-blocking pattern 320 may be overlapped with the pixel isolation structure DTI, when viewed in a plan view. That is, the light-blocking pattern 320 may include portions, which are extended in the first direction D1, and portions, which is extended in the second direction D2. A width of the light-blocking pattern 320 may be substantially equal to or smaller than the smallest width of the pixel isolation structure DTI. The light-blocking pattern 320 may be formed of or include at least one of metallic materials (e.g., titanium, tantalum, or tungsten).

Instead of the light-blocking pattern 320, a low-refractive pattern may be disposed on the planarization insulating layer 310. The low-refractive pattern may be formed of a material whose refractive index is lower than the light-blocking pattern 320. The low-refractive pattern may be formed of or include an organic material and may have a refractive index of about 1.1 to 1.3. For example, the light-blocking pattern 320 may be a polymer layer containing silica nano particles.

The protection layer 330 may cover the planarization insulating layer 310 and the light-blocking pattern 320. The protection layer 330 may have a substantially constant thickness. The protection layer 330 may be a single- or multi-layered structure including at least one of an aluminum oxide layer and a silicon carbon oxide layer.

The color filters may be formed on regions of the protection layer 330 corresponding to the pixel regions PR. The color filters may fill a space that is defined by the light-blocking pattern 320. The color filters may include red, green, or blue color filters or magenta, cyan, or yellow color filters, and in this case, the colors of the color filters may be determined based on positions of the unit pixels.

The color filters may constitute color filter groups ECFG and CCFG, which are arranged in n rows and n columns. FIGS. 5A, 5B, and 7 illustrate only four color filter groups CFG_a, CFG_b, CFG_c, CFG_d, CFG_e, and CFG_f, which are some of the color filter groups ECFG and CCFG, for convenience in illustration. Each of the color filter groups CFG_a, CFG_b, CFG_c, CFG_d, CFG_e, and CFG_f may be composed of color filters, which are arranged in n rows and n columns, and may include first to fourth color filters CF1_a to CF4_a, CF1_b to CF4_b, CF1_c to CF4_c, CF1_d to CF4_d, and CF1_e to CF4_e. As an example embodiment, the color filter groups CFG_a, CFG_b, CFG_c, CFG_d, CFG_e, and CFG_f, which are arranged in 2 rows and 2 columns, may be illustrated in FIGS. 5A to 10.

The center color filter groups CCFG may be disposed on the center pixel region CR of FIG. 4, and the edge color filter groups ECFG may be disposed on the edge pixel region ER of FIG. 4. The center color filter groups CCFG and the edge color filter groups ECFG may be different from each other in their positions on the pixel array region R1 of FIG. 4. For example, the edge color filter groups ECFG may be disposed to enclose the center color filter groups CCFG, when viewed in a plan view.

The micro lenses 340a and 340b may be disposed on the color filters. In detail, the micro lenses 340a and 340b may be disposed to cover the color filter groups CCFG and ECFG, respectively. As an example, each of the micro lenses 340a and 340b may cover one color filter group CFG_a, CFG_b, CFG_c, CFG_d, CFG_e, or CFG_f, in which the color filters are arranged in 2 rows and 2 columns.

The micro lenses 340a and 340b may include first micro lens 340a covering the edge color filter groups ECFG and second micro lenses 340b covering the center color filter groups CCFG. When viewed in a plan view, the centers of the first micro lenses 340a may be shifted from the centers of the edge color filter groups ECFG, respectively. For example, the center of the first micro lenses 340a may be shifted in a direction toward the center of the pixel array region R1 of FIG. 3. Thus, light, which is incident into the edge pixel region ER of FIG. 4, may be incident to a region close to the center of the edge pixel region ER of FIG. 4.

The micro lenses 340a and 340b may have a convex shape and may have a specific curvature radius. The micro lenses 340a and 340b may include an optically transparent resin.

The passivation layer may be provided on micro lenses 340 to conformally cover surfaces of the micro lenses 340a and 340b. As an example, the passivation layer may be formed of or include an inorganic oxide material.

The color filter groups will be described with reference to FIGS. 9 and 10.

Each of color filter groups CFG_1, CFG_2, CFG_3, and CFG_4 (CFG) may include first to fourth color filters CF1, CF2, CF3, and CF4, which are arranged in 2 rows and 2 columns. In the color filter groups CFG_1, CFG_2, CFG_3, and CFG_4 (CFG), the first and second color filters CF1 and CF2 may be disposed to face each other in a diagonal direction, and the third and fourth color filters CF3 and CF4 may be disposed to face each other in a diagonal direction.

Referring to FIG. 9, the first to fourth color filters CF1, CF2, CF3, and CF4 in each of the color filter groups CFG_1, CFG_2, CFG_3, and CFG_4 may be configured to have the same color. As an example, each of the first to fourth color filters CF1, CF2, CF3, and CF4 in each of the color filter groups CFG_1, CFG_2, CFG_3, and CFG_4 may be one of red, green, and blue color filters. As another example, the first to fourth color filters CF1, CF2, CF3, and CF4 in each of the color filter groups CFG_1, CFG_2, CFG_3, and CFG_4 may be provided to have complementary colors such as cyan, magenta, or yellow.

Referring to FIG. 10, the first to fourth color filters CF1, CF2, CF3, and CF4 in each of the color filter groups CFG may be configured to have different colors. As an example, each of the first and second color filters CF1 and CF2 may include a green color filter, the third color filter CF3 may include a blue color filter, and the fourth color filter CF4 may include a red color filter. In each of the color filter groups CFG, the first to fourth color filters CF1, CF2, CF3, and CF4 may be arranged in a Bayer pattern. As another example, the first to fourth color filters CF1, CF2, CF3, and CF4 in each of the color filter groups CFG_1, CFG_2, CFG_3, and CFG_4 may be provided to have complementary colors such as cyan, magenta, or yellow.

Referring back to FIGS. 5A to 6C, the edge color filter groups ECFG and ECFG′ may include first to fourth edge color filter groups CFG_a, CFG_b, CFG_c, and CFG_d, which are disposed adjacent to each other. The first edge color filter group CFG_a may include first to fourth color filters CF1_a, CF2_a, CF3_a, and CF4_a. Similarly, the second to fourth edge color filter groups CFG_b, CFG_c, and CFG_d may include first to fourth color filters (CF1_b, CF2_b, CF3_b, and CF4_b/CF1_c, CF2_c, CF3_c, and CF4_c/CF1_d, CF2_d, CF3_d, and CF4_d), respectively.

FIG. 5A illustrates the edge color filter groups ECFG, which are disposed at the upper right corner of the pixel array region R1 of FIG. 4. The second edge color filter group CFG_b may be a color filter group, which is located in an upper right direction from the first edge color filter group CFG_a and is far from the center pixel region CR of FIG. 4. Furthermore, in the first edge color filter groups CFG_a, the second color filter CF2_a may be a color filter, which is located in an upper right direction from the first color filter CF1_a and is far from the center pixel region CR of FIG. 4 compared to the first color filter CF1_a. Similarly, the second color filters CF2_b, CF2_c, and CF2_d in the second to fourth edge color filter groups CFG_b, CFG_c, and CFG_d may mean color filters, which are far from the center pixel region CR of FIG. 4 compared to the first color filters CF1_b, CF1_c, and CF1_d.

FIG. 5B illustrates the edge color filter groups ECFG′, which are disposed at the lower left corner of the pixel array region R1 of FIG. 4. The second edge color filter group CFG_b may be a color filter group, which is located in a lower left direction from the first edge color filter group CFG_a and is far from the center pixel region CR of FIG. 4. Furthermore, in the first edge color filter groups CFG_a, the second color filter CF2_a may be a color filter, which is located in a lower left direction from the first color filter CF1_a and is far from the center pixel region CR of FIG. 4 compared to the first color filter CF1_a. Similarly, the second color filters CF2_b, CF2_c, and CF2_d in the second to fourth edge color filter groups CFG_b, CFG_c, and CFG_d may mean color filters, which are far from the center pixel region CR of FIG. 4 compared to the first color filters CF1_b, CF1_c, and CF1_d.

In the present specification, the following description refers to the edge color filters, which are placed at the upper right corner of the pixel array region R1 of FIG. 4, as shown in FIG. 5A, for convenience in description. However, the second to fourth edge color filter groups may be color filter groups, which are far from the center pixel region CR of FIG. 4 compared to the first edge color filter group. Furthermore, in each edge color filter group, the second to fourth color filters may be color filters, which are far from the center pixel region compared to the first color filter.

In the first edge color filter group CFG_a, the second color filter CF2_a may be disposed near an edge of the pixel array region R1 of FIG. 3 compared to the first color filter CF1_a. Similarly, the third and fourth color filters CF3_a and CF4_a may be located at positions that are far from the center pixel region CR of FIG. 4 compared to the first color filter CF1_a but are adjacent to the first and second color filters CF1_a and CF2_a.

In the first edge color filter group CFG_a, the first to fourth color filters CF1_a, CF2_a, CF3_a, and CF4_a may have different thicknesses from each other. For example, a thickness T2a of the second color filter CF2_a may be smaller than a thickness Tla of the first color filter CF1_a. Furthermore, thicknesses T3a and T4a of the third and fourth color filters CF3_a and CF4_a may also be smaller than the thickness Tla of the first color filter. Here, a thickness of each of the first to fourth color filters CF1_a, CF2_a, CF3_a, and CF4_a may mean a length measured in the third direction D3.

The first edge color filter group CFG_a may be disposed near an edge of the pixel array region R1 of FIG. 4, unlike the center color filter groups CCFG, and thus, light may not be perpendicularly incident into the first edge color filter group CFG_a and may be incident obliquely into an edge region of the first edge color filter group CFG_a. Depending on an incident angle of the light, a propagation length of the light passing through the color filter may be different from a thickness of the color filter. Furthermore, in the first edge color filter group CFG_a disposed at an edge of the pixel array R1 of FIG. 3, an incident angle of the light passing through the first color filter CF1_a may be different from an incident angle of the light passing through the second color filter CF2_a. Here, since the second color filter CF2_a is disposed outside the first color filter CF1_a, the incident angle of the light passing through the second color filter CF2_a may be greater than the incident angle of the light passing through the first color filter CF1_a. In the case where the first to fourth color filters CF1_a, CF2_a, CF3_a, and CF4_a have the same thickness, a light amount of the incident light passing through the second color filter CF2_a may be smaller than a light amount of the incident light passing through the first color filter CF1_a. Thus, there may be a difference in light amount between the lights passing through the first and second color filters CF1_a and CF2_a. This may lead to a channel difference issue in the image sensor.

By contrast, according to an embodiment, the second color filter CF2_a may be formed to have the thickness T2a that is smaller than the thickness Tla of the first color filter CF1_a, and thus, the optical paths of the lights passing through the first and second color filters CF1_a and CF2_a may have substantially the same lengths. Similarly, the third and fourth color filters CF3_a and CF4_a may be formed to have the thicknesses T3a and T4a that are smaller than the thickness Tla of the first color filter, and in this case, the optical paths of the lights passing through the first, third, and fourth color filters CF1_a, CF3_a, and CF4_a may have substantially the same length. Thus, it may be possible to prevent the channel difference issue, which may occur in the image sensor.

Similar to the first edge color filter group CFG_a described above, the first to fourth color filters (CF1_b, CF2_b, CF3_b, and CF4_b/CF1_c, CF2_c, CF3_c, and CF4_c/CF1_d, CF2_d, CF3_d, and CF4_d) may be disposed in the second to fourth edge color filter groups CFG_b, CFG_c, and CFG_d, and two color filters of the first to fourth color filters (CF1_b, CF2_b, CF3_b, and CF4_b/CF1_c, CF2_c, CF3_c, and CF4_c/CF1_d, CF2_d, CF3_d, and CF4_d) may have different thicknesses from each other.

Next, a difference in thickness of the first to fourth color filters (CFla, CF2_a, CF3_a, and CF4_a/CF1_b, CF2_b, CF3_b, and CF4_b/CF1_c, CF2_c, CF3_c, and CF4_c/CF1_d, CF2_d, CF3_d, and CF4_d) between the edge color filter groups ECFG will be described below.

The first edge color filter group CFG_a and the second edge color filter group CFG_b may be disposed to face each other in a diagonal direction. Here, the second edge color filter group CFG_b may be disposed near the edge of the pixel array region R1 of FIG. 3 compared with the first edge color filter group CFG_a.

The first and second color filters CF1_b and CF2_b of the second edge color filter group CFG_b may be placed further away from the center pixel region CR of FIG. 4 compared to the first and second color filters CF1_a and CF2_a of the first edge color filter group CFG_a. In other words, the first and second color filters CF1_b and CF2_b of the second edge color filter group CFG_b may be disposed near the edge of the pixel array region R1 of FIG. 3 compared to the first and second color filters CF1_a and CF2_a of the first edge color filter group CFG_a. The incident angle of the incident light may be further deviated from the right angle as it moves from the center of the pixel array region R1 of FIG. 3 to the edge of the pixel array region R1. Accordingly, the channel difference issue described above may occur more seriously in the second to fourth edge color filter groups CFG_b, CFG_c, and CFG_d, which are placed near the edge of the pixel array region R1 of FIG. 3.

According to an embodiment, the second color filter CF2_b of the second edge color filter group CFG_b may be formed to have a thickness T2b that is smaller than a thickness T1b of the first color filter CF1_b of the second edge color filter group CFG_b, and in this case, it may be possible to prevent or suppress the channel difference issue in the color filter group. Moreover, the thickness T2b of the second color filter CF2_b of the second edge color filter group CFG_b may be smaller than the thickness T2a of the second color filter CF2_a of the first edge color filter group CFG_a. In other words, the first and second color filters of the second edge color filter group CFG_b may be formed such that a difference between the thicknesses Tlb and T2b of them is larger than a difference between the thicknesses Tla and T2a of the first and second color filters of the first edge color filter group CFG_a. As an example, the first color filters CF1_a, CF1_b, CF1_c, and CF1_d of the edge color filter groups ECFG may be formed to have substantially the same thickness, and the thicknesses of the second color filters CF2_a, CF2_b, CF2_c, and CF2_d of the edge color filter groups ECFG may gradually decrease as it moves toward the edge of the pixel array region R1 of FIG. 4. However, in an embodiment, at least two ones of the first color filters CF1_a, CF1_b, CF1_c, and CF1_d of the edge color filter groups ECFG may have different thicknesses from each other.

The first and third color filters CF1_c and CF3_c of the third edge color filter group CFG_c may be placed further away from the center pixel region CR of FIG. 4 compared to the first and third color filters CF1_a and CF3_a of the first edge color filter group CFG_a. Similarly, a thickness T3c of the third color filter of the third edge color filter group CFG_c may be smaller than the thickness T3a of the third color filter CF3_a of the first edge color filter group CFG_a and may prevent the channel difference issue in the third edge filter group CFG_c.

In addition, the first and fourth color filters CF1_d and CF4_d of the fourth edge color filter group CFG_d may be placed further away from the center pixel region CR of FIG. 4 compared to the first and fourth color filters CF1_a and CF4_d of the first edge color filter group CFG_a. Similarly, a thickness T4d of the fourth color filter CF4_d of the fourth edge color filter group CFG_d may be smaller than a thickness T4a of the fourth color filter CF4_a of the first edge color filter group CFG_a and may prevent the channel difference issue in the fourth edge filter group CFG_d. Below, in order to provide a concise explanation, the same features as the first and second edge color filter groups CFG_a and CFG_b will be omitted.

Referring to FIGS. 7 to 8C, the center color filter groups CCFG may include a plurality of color filter groups CFG_e and CFG_f, which are disposed adjacent to each other. In the present specification, a first center color filter group CFG_e, which is one of the center color filter groups CCFG, will be described as a representative example of the center color filter groups CCFG, for convenience in description.

The first center color filter group CFG_e may include first to fourth color filters CF1_e, CF2_e, CF3_e, and CF4_e. In the first center color filter group CFG_e, thicknesses Tle, T2e, T3e, and T4e of the first to fourth color filters CF1_e, CF2_e, CF3_e, and CF4_e may be substantially equal to each other.

In the first center color filter group CFG_e, most of the light may be incident perpendicularly to the first surface 100a of the semiconductor substrate 100. That is, most of the lights passing through the color filters CF1_e, CF2_e, CF3_e, and CF4_e in the first center color filter group CFG_e may be incident with the right angle, and there may be no difference in the incident angles therebetween. Accordingly, the channel difference issue may not occur, even when the color filters CF1_e, CF2_e, CF3_e, and CF4_e in the first center color filter group CFG_e have the same thickness.

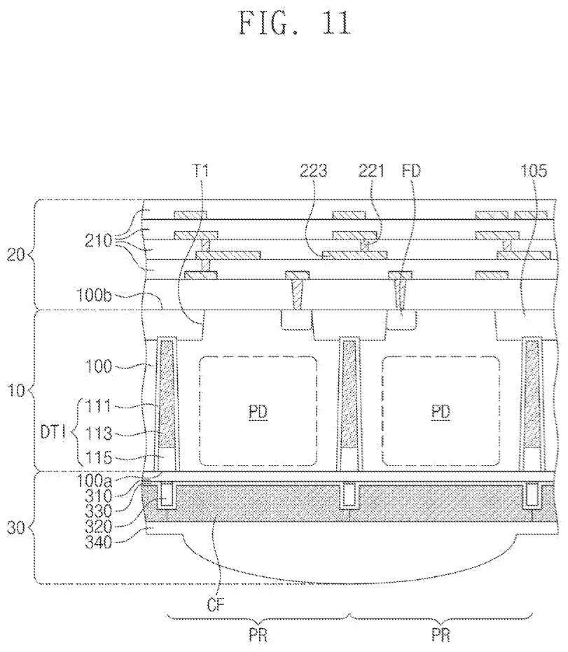

FIGS. 11 to 13 are sectional views illustrating image sensors according to some embodiments. In the following description, an element previously described with reference to FIGS. 5A to 10 may be identified by the same reference number without repeating an overlapping description thereof, for concise description.

Referring to FIG. 11, the pixel isolation structure DTI may have an upper width at a level near the second surface 100b of the semiconductor substrate 100. A pixel isolation structure PIS may have a lower width at a level near the second surface 100b of the semiconductor substrate 100. The upper width may be smaller than the lower width. For example, the width of the pixel isolation structure DTI may decrease gradually as it moves from the first surface 100a of the semiconductor substrate 100 to the second surface 100b.

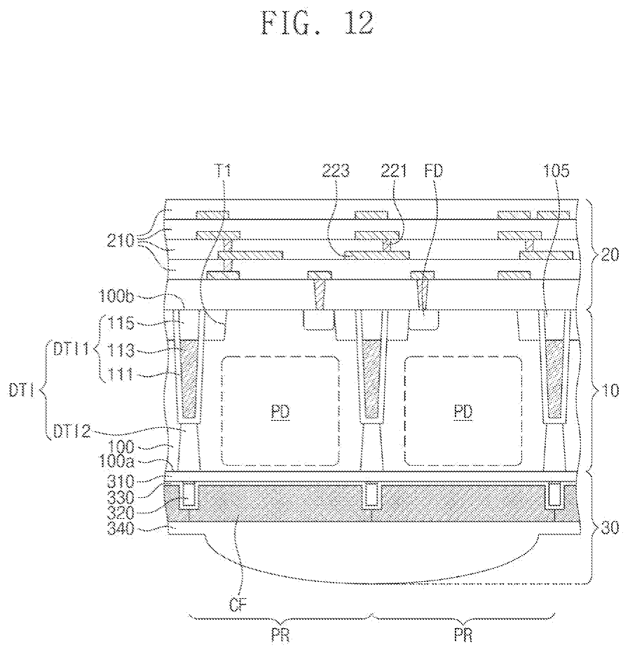

Referring to FIG. 12, the pixel isolation structure DTI may have an upper width at a level near the second surface 100b of the semiconductor substrate 100. The pixel isolation structure DTI may have a lower width at a level near the first surface 100a of the semiconductor substrate 100. The pixel isolation structure DTI may have an intermediate width in the semiconductor substrate 100. Each of the upper and lower widths may be larger than the intermediate width. The width of the pixel isolation structure DTI may decrease and then increase as it goes from the second surface 100b of the semiconductor substrate 100 to the first surface 100a. For example, the width of the pixel isolation structure DTI may have the largest value near the first and second surfaces 100a and 100b of the semiconductor substrate 100 and may have the smallest value in the semiconductor substrate 100.

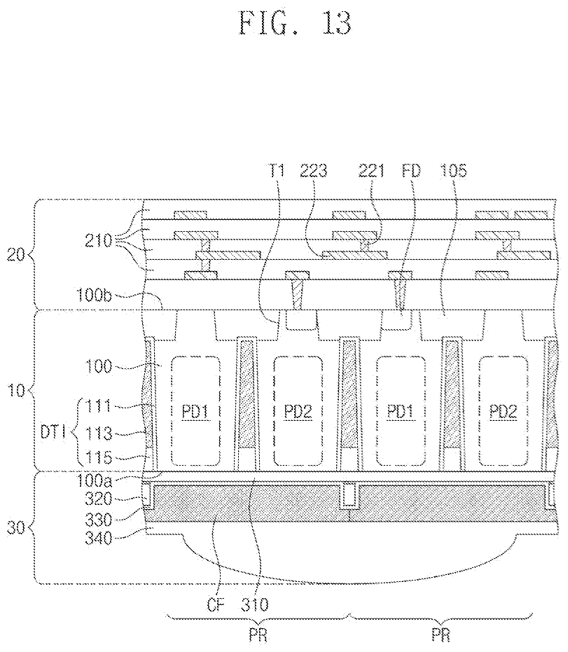

Referring to FIG. 13, each pixel region PR may include first and second photoelectric conversion regions PD1 and PD2. The first and second photoelectric conversion regions PD1 and PD2 may be impurity regions, which are doped with impurities that have a different conductivity type (e.g., the second conductivity type or n-type) from the semiconductor substrate 100 of the first conductivity type.

The pixel isolation structure DTI may be disposed between the first photoelectric conversion region PD1 and the second photoelectric conversion region PD2. The pixel isolation structure DTI may prevent a cross-talk issue from occurring between the first and second photoelectric conversion regions PD1 and PD2. For example, the pixel isolation structure DTI may prevent light, which is incident into the first photoelectric conversion region PD1, from entering the second photoelectric conversion region PD2.

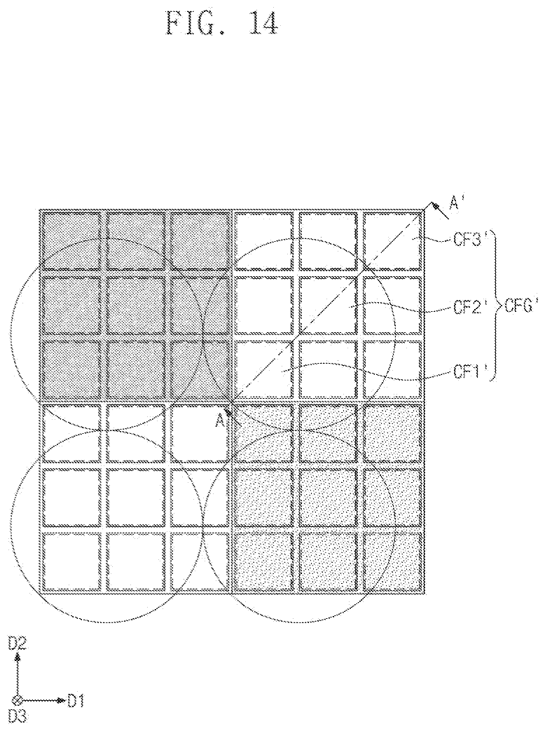

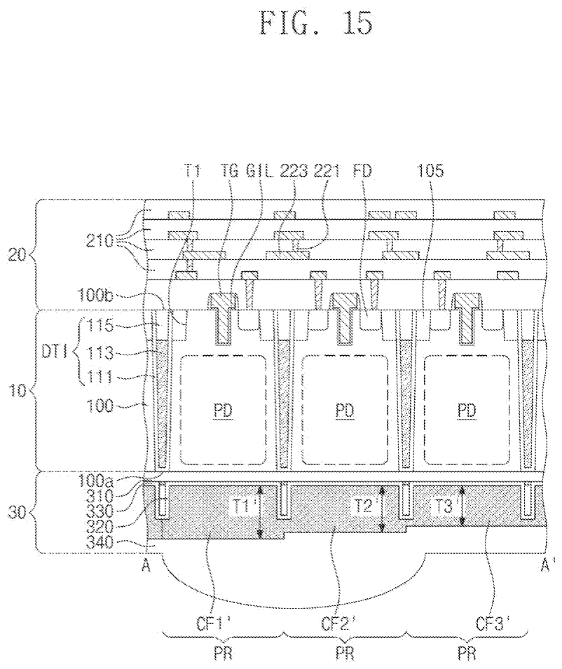

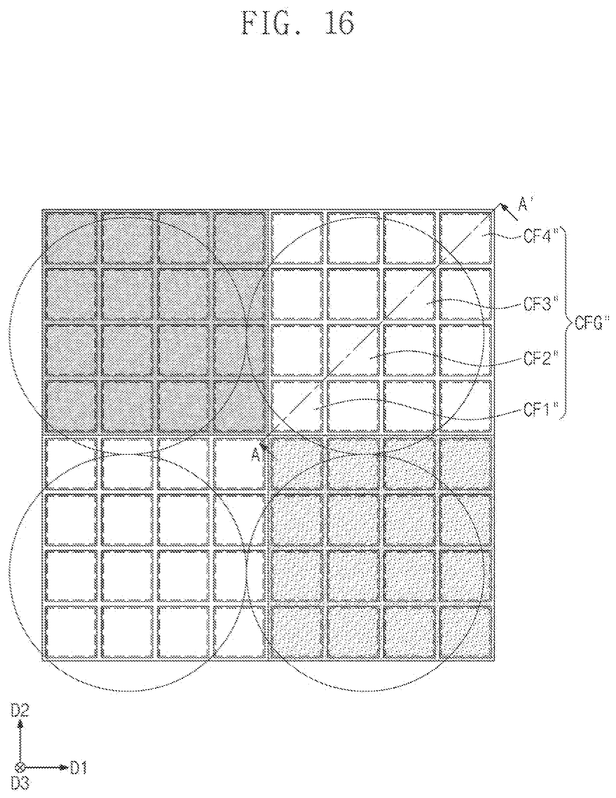

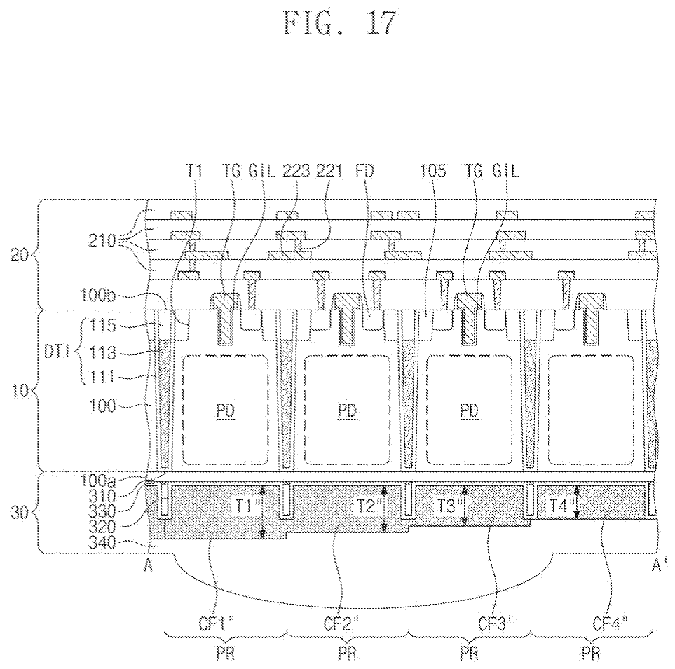

FIG. 14 is a plan view illustrating an image sensor according to an embodiment. FIG. 15 is a sectional view, which is taken along a line A-A′ of FIG. 14 to illustrate an image sensor according to an embodiment. FIG. 16 is a plan view illustrating an image sensor according to an embodiment. FIG. 17 is a sectional view, which is taken along a line A-A′ of FIG. 16 to illustrate an image sensor according to an embodiment. In the following description, an element previously described with reference to FIGS. 5A to 10 may be identified by the same reference number without repeating an overlapping description thereof, for concise description.

Referring to FIGS. 14 and 15, each of color filter groups CFG′ may include nine color filters CF1′, CF2′, and CF3′, which are arranged in 3 rows and 3 columns. For convenience in description, color filters, which are arranged in a diagonal direction in the color filter groups CFG′, will be referred to as first to third color filters CF1′, CF2′, and CF3′.

An incident angle of light passing through the first color filter CF1′, an incident angle of light passing through the second color filter CF2′, and an incident angle of light passing through the third color filter CF3′ may be different from each other. Here, the third color filter CF3′, the second color filter CF2′, and the first color filter CF1′ may be placed close to the edge of the pixel array region R1 of FIG. 3 in the order enumerated. Thus, an averaged incident angle of the light incident into the color filter may decrease as it moves toward the third color filter CF3′, the second color filter CF2′, or the first color filter CF1′.

According to an embodiment, thicknesses of the first to third color filters CF1′, CF2′, and CF3′ may decrease as they go from the first color filter CF1′ to the third color filter CF3′. For example, a thickness T3′ of the third color filter CF3′ may be smaller than a thickness T2′ of the second color filter CF2′, and the thickness T2′ of the second color filter CF2′ may be smaller than a thickness T1′ of the first color filter CF1′. Accordingly, lengths of the optical paths of the lights passing through the first to third color filters CF1′, CF2′, and CF3′ may be substantially equal to each other. As a result, it may be possible to prevent the channel difference issue, which may occur in the image sensor.

Referring to FIGS. 16 and 17, each of color filter groups CFG″ may include sixteen color filters, which are arranged in 4 rows and 4 columns. For convenience in description, color filters, which are arranged in a diagonal direction in the color filter groups CFG″, will be referred to as first to fourth color filters CF1″, CF2″ CF3″, and CF4″.

In the color filter groups CFG″, an incident angle of light passing through the first color filter CF1″, an incident angle of light passing through the second color filter CF2″, an incident angle of light passing through the third color filter CF3″, and an incident angle of light passing through the fourth color filter CF4″ may be different from each other. Here, the fourth color filter CF4″, the third color filter CF3″, the second color filter CF2″, and the first color filter CF1″ may be placed close to the edge of the pixel array region R1 of FIG. 3 in the order enumerated. Thus, mean values of the incident angles of the lights, which are incident into the first to fourth color filters CF1″, CF2″, CF3″, and CF4″, may gradually decrease in the following order: the fourth color filter CF4″, the third color filter CF3″, the second color filter CF2″, and the first color filter CF1″.

According to an embodiment, thicknesses of the first to fourth color filters CF1″, CF2″, CF3″, and CF4″ may decrease as they go from the first color filter CF1″ to the fourth color filter CF4″. For example, a thickness T4″ of the fourth color filter CF4″ may be smaller than a thickness T3″ of the third color filter CF3″, the thickness T3″ of the third color filter CF3″ may be smaller than a thickness T2″ of the second color filter CF2″, and the thickness T2″ of the second color filter CF2″ may be smaller than a thickness T1″ of the first color filter CF1″. Accordingly, lengths of the optical paths of the lights passing through the first to fourth color filters CF1″, CF2″, CF3″, and CF4″ may be substantially equal to each other. As a result, it may be possible to prevent the channel difference issue, which may occur in the image sensor.

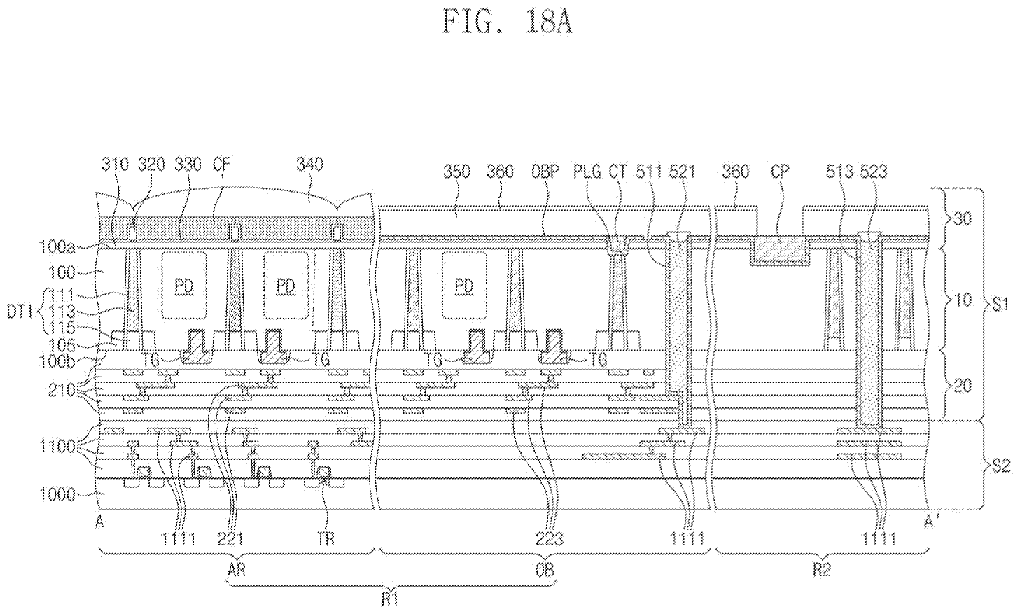

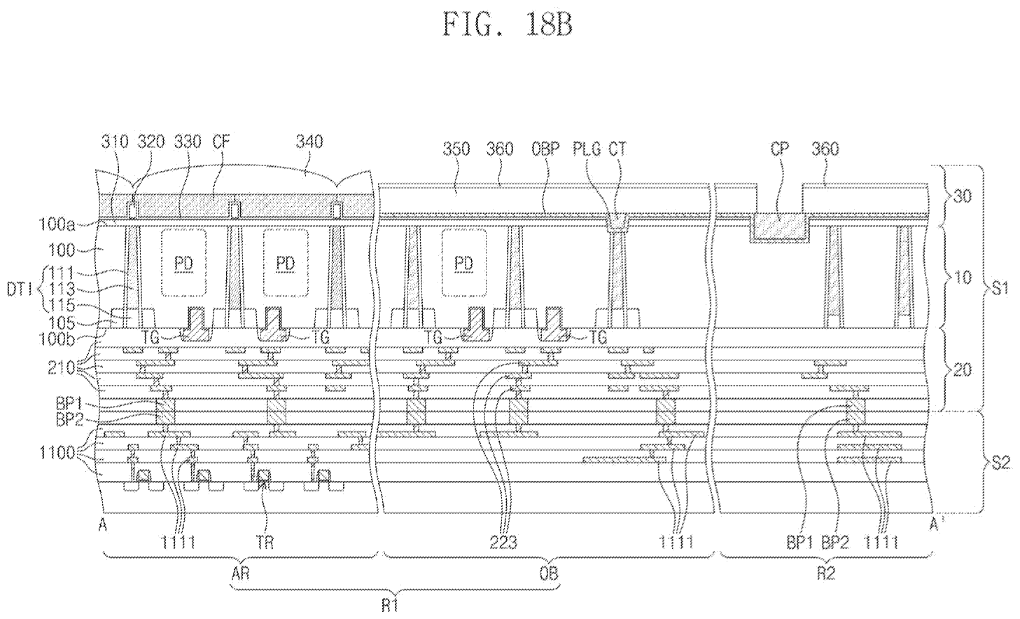

FIGS. 18A and 18B are sectional views, each of which is taken along the line A-A′ of FIG. 4 to illustrate an image sensor according to an embodiment.

Referring to FIGS. 4, 18A, and 18B, the image sensor may include a sensor chip S1 and a logic chip S2. The sensor chip S1 may include the pixel array region R1 and the pad region R2.

A plurality of conductive pads CP, which are used to input or output control signals and photoelectric signals, may be disposed in the pad region R2. The pad region R2 may be provided to enclose the pixel array region R1, when viewed in a plan view, and in this case, the image sensor may be easily connected to an external device. The conductive pads CP may be used to transmit electrical signals, which are generated in the unit pixels P, to an external device.

In the light-receiving region AR, the sensor chip S1 may be configured to have the same technical features as the image sensor described above. That is, when viewed in a vertical section, the sensor chip S1 may include the pixel circuit layer 20, the optically-transparent layer 30, and the photoelectric conversion layer 10 therebetween, as described above. The photoelectric conversion layer 10 of the sensor chip S1 may include the semiconductor substrate 100, the pixel isolation structure DTI defining the pixel regions, and the photoelectric conversion regions PD provided in the pixel regions, as described above. The pixel isolation structure DTI may have substantially the same structure in the light-receiving region AR and the light-blocking region OB.

In the light-blocking region OB, the optically-transparent layer 30 may include a light-blocking pattern OBP, a back-side contact plug PLG, a contact pattern CT, an organic layer 350, and a passivation layer 360.

A portion of the pixel isolation structure DTI may be connected to the back-side contact plug PLG in the light-blocking region OB.

In detail, a semiconductor pattern 113 may be connected to the back-side contact plug PLG, in the light-blocking region OB. A negative bias may be applied to the semiconductor pattern 113 through the contact pattern CT and the back-side contact plug PLG. In this case, it may be possible to reduce a dark current which may be generated at an interface between the pixel isolation structure DTI and the semiconductor substrate 100.

The back-side contact plug PLG may have a width that is larger than a width of the pixel isolation structure DTI. The back-side contact plug PLG may be formed of or include at least one of metallic materials and/or metal nitride materials. For example, the back-side contact plug PLG may be formed of or include at least one of titanium and/or titanium nitride.

The contact pattern CT may be buried in a contact hole, in which the back-side contact plug PLG is formed. The contact pattern CT may include a material that is different from the back-side contact plug PLG. For example, the contact pattern CT may be formed of or include aluminum (Al).

The contact pattern CT may be electrically connected to the semiconductor pattern 113 of the pixel isolation structure DTI. The contact pattern CT may be used to apply a negative bias to the semiconductor pattern 113 of the pixel isolation structure DTI, and in this case, the negative bias may be supplied from the light-blocking region OB to the light-receiving region AR.

In the light-blocking region OB, the light-blocking pattern OBP may be continuously extended from the back-side contact plug PLG and may be disposed on a top surface of the planarization insulating layer 310. In other words, the light-blocking pattern OBP may be formed of or include the same material as the back-side contact plug PLG. The light-blocking pattern OBP may be formed of or include at least one of metallic materials and/or metal nitride materials. For example, the light-blocking pattern OBP may be formed of or include at least one of titanium and/or titanium nitride. The light-blocking pattern OBP may not be extended to the light-receiving region AR of the pixel array region R1.

The light-blocking pattern OBP may prevent light from being incident into the photoelectric conversion regions PD, which are provided in the light-blocking region OB. The photoelectric conversion regions PD in the reference pixel regions of the light-blocking region OB may be configured to output a noise signal, not a photoelectric signal. The noise signal may be produced by electrons, which are generated by heat or a dark current.

In the light-blocking region OB, the organic layer 350 and the passivation layer 360 may be provided on the light-blocking pattern OBP. The organic layer 350 may be formed of or include the same material as the micro lenses 340.

In the light-blocking region OB, a first penetration conductive pattern 511 may be provided to penetrate the semiconductor substrate 100 and may be electrically connected to the metal lines 223 of the pixel circuit layer 20 and an interconnection structure 1111 of the logic chip S2. The first penetration conductive pattern 511 may have a first bottom surface and a second bottom surface, which are located at different levels. A first gapfill pattern 521 may be provided in the first penetration conductive pattern 511. The first gapfill pattern 521 may be formed of or include at least one of low refractive materials and may have an insulating property.

In the pad region R2, the conductive pads CP may be provided on the second surface 100b of the semiconductor substrate 100. The conductive pads CP may be buried in the semiconductor substrate 100 and near the second surface 100b. In an embodiment, the conductive pads CP may be provided in pad trenches, which are formed in the second surface 100b of the semiconductor substrate 100 and are located in the pad region R2. The conductive pads CP may be formed of or include at least one of metallic materials (e.g., aluminum, copper, tungsten, titanium, tantalum, or alloys thereof). In a mounting process of an image sensor, bonding wires may be bonded to the conductive pads CP. The conductive pads CP may be electrically connected to an external device through the bonding wires.

In the pad region R2, a second penetration conductive pattern 513 may be provided to penetrate the semiconductor substrate 100 and may be electrically connected to the interconnection structure 1111 of the logic chip S2. The second penetration conductive pattern 513 may be extended to a region on the second surface 100b of the semiconductor substrate 100 and may be electrically connected to the conductive pad CP. A portion of the second penetration conductive pattern 513 may cover bottom and side surfaces of the conductive pads CP. A second gapfill pattern 523 may be provided in the second penetration conductive pattern 513. The second gapfill pattern 523 may be formed of or include at least one of low refractive materials and may have an insulating property. In the pad region R2, pixel isolation structures DTI may be provided around the second penetration conductive pattern 513.

The logic chip S2 may include a logic semiconductor substrate 1000, logic circuits TR, interconnection structures 1111 connected to the logic circuits, and logic interlayer insulating layers 1100. The uppermost layer of the logic interlayer insulating layers 1100 may be bonded to the pixel circuit layer 20 of the sensor chip S1. The logic chip S2 may be electrically connected to the sensor chip S1 through the first and second penetration conductive patterns 511 and 513.

In an embodiment, the sensor and logic chips S1 and S2 are illustrated to be electrically connected to each other through the first and second penetration conductive patterns 511 and 513, but embodiments of the disclosure are not limited to this example.

Referring to FIG. 18B, the first and second penetration conductive patterns 511 and 513 of FIG. 18A may be omitted, and bonding pads, which are provided in the uppermost metal layers of the sensor and logic chips S1 and S2, may be directly bonded to each other to electrically connect the sensor and logic chips S1 and S2 to each other.

In more detail, the sensor chip S1 of the image sensor may include first bonding pads BP1, which are provided in the uppermost metal layer of the pixel circuit layer 20, and the logic chip S2 may include second bonding pads BP2, which are provided in the uppermost metal layer of the interconnection structure 1111. The first and second bonding pads BP1 and BP2 may be formed of or include at least one of, for example, tungsten (W), aluminum (Al), copper (Cu), tungsten nitride (WN), tantalum nitride (TaN), or titanium nitride (TiN).

The first bonding pads BP1 of the sensor chip S1 and the second bonding pads BP2 of the logic chip S2 may be electrically and directly connected to each other by a hybrid bonding method. Here, the hybrid bonding method may mean a method of bonding two materials of the same kind at an interface therebetween (e.g., through a fusion process). For example, in the case where the first and second bonding pads BP1 and BP2 are formed of copper (Cu), they may be physically and electrically connected to each other in a Cu—Cu bonding manner. In addition, surfaces of insulating layers of the sensor and logic chips S1 and S2 may be bonded to each other in a dielectric-dielectric bonding manner.

According to an embodiment, it may be possible to improve optical properties of an image sensor.

While certain example embodiments the disclosure have been particularly shown and described, it will be understood that various changes in form and details may be made therein without departing from the spirit and scope of the following claims.

What is claimed is:

1. An image sensor comprising:
a semiconductor substrate comprising a pixel array region, the pixel array region comprising a center pixel region and an edge pixel region enclosing the center pixel region in a plan view;
color filter groups on the pixel array region, each color filter group of the color filter groups comprising color filters arranged in a same number of rows and columns; and
micro lenses covering the color filter groups, respectively,
wherein the color filter groups comprise center color filter groups on the center pixel region and edge color filter groups on the edge pixel region, and
wherein at least two color filters of the color filters in each of the edge color filter groups have thicknesses that are different from each other.

2. The image sensor of claim 1, wherein each edge color filter group of the edge color filter groups comprises a first color filter, a second color filter, a third color filter, and a fourth color filter, and
wherein a thickness of the first color filter is larger than a thickness of the second color filter.

3. The image sensor of claim 2, wherein the second color filter is further from the center pixel region than is the first color filter.

4. The image sensor of claim 2, wherein the second color filter, the third color filter, and the fourth color filter are further from the center pixel region than is the first color filter,
wherein the second color filter faces the first color filter in a diagonal direction, and
wherein a thickness of the third color filter and a thickness of the fourth color filter are smaller than the thickness of the first color filter.

5. The image sensor of claim 2, wherein the edge color filter groups comprise a first edge color filter group and a second edge color filter group, and the second edge color filter group is further from the center pixel region than is the first edge color filter group, and
wherein the thickness of the second color filter of the second edge color filter group is smaller than the thickness of the second color filter of the first edge color filter group.

6. The image sensor of claim 5, wherein the thickness of the first color filter of the second edge color filter group is substantially the same as the thickness as the first color filter of the first edge color filter group.

7. The image sensor of claim 1, wherein, in the center color filter groups, the color filters have substantially a same thickness.

8. The image sensor of claim 1, wherein the micro lenses comprise first micro lenses covering the edge color filter groups and second micro lenses covering the center color filter groups, and
wherein centers of the first micro lenses are shifted from respective centers of the edge color filter groups, when viewed in the plan view.

9. The image sensor of claim 1, further comprising a pixel isolation structure in the semiconductor substrate, the pixel isolation structure defining a plurality of pixel regions in the pixel array region.

10. The image sensor of claim 9, wherein the semiconductor substrate comprises a first surface and a second surface, which are opposite to each other,
wherein the color filter groups are on the first surface, and
wherein a width of the pixel isolation structure increases from the first surface to the second surface.

11. The image sensor of claim 9, wherein the semiconductor substrate comprises a first surface and a second surface, which are opposite to each other,
wherein the color filter groups are on the first surface, and
wherein a width of the pixel isolation structure decreases from the first surface to the second surface.

12. The image sensor of claim 9, wherein the semiconductor substrate comprises a first surface and a second surface, which are opposite to each other,
wherein the color filter groups are on the first surface, and
wherein a width of the pixel isolation structure has a smallest value, between the first surface and the second surface.

13. An image sensor comprising:
a semiconductor substrate of a first conductivity type, the semiconductor substrate comprising a pixel array region, a first surface and a second surface opposite to the first surface;
a photoelectric conversion region in the pixel array region, the photoelectric conversion region comprising impurities of a second conductivity type;
color filter groups covering at least a portion of the pixel array region, each color filter group of the color filter groups comprising a first color filter, a second color filter, a third color filter, and a fourth color filter arranged in two rows and two columns; and
micro lenses covering the color filter groups, respectively,
wherein the pixel array region comprises a center pixel region and an edge pixel region enclosing the center pixel region in a plan view,
wherein the color filter groups comprise center color filter groups on the center pixel region and edge color filter groups on the edge pixel region, and
wherein, in each edge color filter group of the edge color filter groups, a thickness of the first color filter is larger than a thickness of the second color filter.

14. The image sensor of claim 13, wherein, in each of the edge color filter groups, the second color filter is further from the center pixel region than is the first color filter.

15. The image sensor of claim 13, wherein the edge color filter groups comprise a first edge color filter group and a second edge color filter group which is further from the center pixel region than is the first edge color filter group, and
wherein the thickness of the second color filter of the second edge color filter group is smaller than the thickness of the second color filter of the first edge color filter group.

16. The image sensor of claim 15, wherein the thickness of the first color filter of the second edge color filter group is substantially the same as the thickness as the first color filter of the first edge color filter group.

17. The image sensor of claim 13, further comprising a light-blocking pattern separating the color filter groups from each other.

18. The image sensor of claim 13, wherein, in each color filter group of the color filter groups, the first color filter, the third color filter, and the fourth color filter are of a same color.

19. The image sensor of claim 13, further comprising a pixel isolation structure in the semiconductor substrate and enclosing the photoelectric conversion region in the plan view.

20. An image sensor comprising:
a semiconductor substrate comprising a light-receiving region, a light-blocking region, a pad region, a first surface, and a second surface which is opposite to the first surface;
a pixel isolation structure in the light-receiving region and the light-blocking region of the semiconductor substrate, the pixel isolation structure defining pixel regions;
photoelectric conversion regions in the light-receiving region and the light-blocking region of the semiconductor substrate;
color filter groups on the first surface, each color filter group of the color filter groups comprising a first color filter, a second color filter, a third color filter, and a fourth color filter arranged in two rows and two columns;
a transfer gate electrode on the second surface;
a pixel circuit layer on the second surface; and
micro lenses covering the color filter groups, respectively,
wherein the light-receiving region comprises a center pixel region and an edge pixel region enclosing the center pixel region in a plan view,
wherein the color filter groups comprise center color filter groups on the center pixel region and edge color filter groups on the edge pixel region, and
wherein, in each of the edge color filter groups, a thickness of the first color filter is larger than a thickness of the second color filter.
